(19) United States
(12) Patent Application Publication
(10) Pub. No.: US 2010/0015800 A1
(43) Pub. Date: Jan. 21, 2010

(54) METHOD FOR FORMING METAL FILM USING CARBONYL MATERIAL, METHOD FOR FORMING MULTI-LAYER WIRING STRUCTURE, AND METHOD FOR MANUFACTURING SEMICONDUCTOR DEVICE

(75) Inventors: Masamichi HARA, Nirasaki-shi (JP); Tatsuo Hatano, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/568,082

(22) Filed: Sep. 28, 2009

Related U.S. Application Data
(63) Continuation of application No. PCT/JP08/52459, filed on Feb. 14, 2008.

(30) Foreign Application Priority Data
Mar. 28, 2007 (JP) 2007-085021

(51) Int. Cl. H01L 21/768; B05D 5/12; C25D 5/02

(52) U.S. Cl. 438/653; 427/96.8; 205/125; 257/E21.584

(57) ABSTRACT

A film forming method includes a first step of supplying a carbonyl material including a metallic element onto a surface of a substrate to be processed in a form of gas phase molecules along with a suppressor gas suppressing a decomposition of the carbonyl material, wherein a partial pressure of the suppressor gas is set to a first partial pressure at which the decomposition of the carbonyl material is suppressed; and a second step of changing the partial pressure of the suppressor gas in the surface of the substrate to a second partial pressure which causes the decomposition of the carbonyl material to thereby deposit the metallic element on the surface of the substrate.

This application is a Continuation Application of PCT International Application No. PCT/JP2008/052459 filed on Feb. 14, 2008, which designated the United States.

### FIELD OF THE INVENTION

The present invention generally relates to manufacturing a semiconductor device, and more particularly, to a film forming method and a film forming apparatus for forming a metal film, which are used for forming a multi-layer wiring structure.

### BACKGROUND OF THE INVENTION

In today's ultra-fine semiconductor integrated circuit devices, a multi-layer wiring structure employing a low-resistance metal for a wiring pattern is used to interconnect a great number of semiconductor devices formed on a substrate. In a multi-layer wiring structure employing especially a Cu wiring pattern, there is generally used a damascene method or dual damascene method, wherein a wiring groove or via hole is pre-formed in a silicon oxdie layer or an inter-layer insulation film formed of so-called low dielectric constant (low-K) material of a lower relative dielectric constant, and filled by a Cu layer. Then, an extra portion of the Cu layer is removed by chemical mechanical polishing (CMP).

In the damascene method or dual damascene method, a surface of the wiring groove or via hole formed in the inter-layer insulation film is typically covered by a barrier metal film made of a high-melting point metal such as Ta or TaN or a nitride thereof, and a thin Cu seed layer is formed thereon by a PVD method or CVD method. The wiring groove or via hole is filled with a Cu layer by electroplating it using the Cu seed layer as an electrode.

Patent document 1: Japanese Patent Laid-open Application No. 2004-346401

Patent document 2: Japanese Patent Laid-open Publication No. 2990551

Patent document 3: Japanese Patent Laid-open Application No. 2004-156104

As a semiconductor integrated circuit device is recently becoming smaller and smaller, a diameter of Cu via plug formed in an inter-layer insulation film is decreased from 65 nm to 45 nm. In a near future, a diameter of via plug is expected to be further reduced to 32 nm or 22 nm.

According to miniaturization of semiconductor integrated circuit devices, it becomes difficult in terms of a step coverage to form a barrier metal film or Cu seed layer in such a fine via hole or wiring groove by a conventional PVD method. Therefore, a film forming technology by a MOCVD method or ALD method is studied, which may accomplish an excellent step coverage under such a low temperature that does not damage an inter-layer insulation film made of a low-K material.

However, since the MOCVD method or ALD method generally uses an organic metal material wherein metal atoms are bonded with organic groups, such that impurities to remain in the film formed. Thus, although the film appears to have a good step coverage, film quality thereof is unstable. Moreover, for example, if a Cu seed layer is formed on a Ta barrier metal film by a MOCVD method, the Cu seed layer is apt to be agglomerated and it is difficult to form the Cu seed layer that stably covers the Ta barrier film by a uniform film thickness. If the Cu layer is electroplated by using the agglomerated seed layer as an electrode, any defects may be included in the Cu layer that fills the wiring groove or via hole, which causes problems such as an increase in electric resistance, and deterioration of electron migration resistance or stress migration resistance.

Meanwhile, in the related art of the present invention, there has been suggested a technology in which a Ru film is formed on a Ta barrier film by a CVD method and a Cu seed layer is formed thereon by a MOCVD method so that a uniform Cu seed layer is formed while avoiding the agglomeration of Cu seed layer. In the related art of the present invention, a Ru carbonyl material is supplied onto a surface of a substrate to be processed under a high-concentration Co atmosphere, and decomposition of the Ru carbonyl material is suppressed during being transferred.

Further, if a semiconductor integrated circuit device is further finer and, for example, a diameter of a via hole formed in an inter-layer insulation film becomes 22 nm or less, it is considered that a step coverage accomplishable by the CVD method has a limitation, which makes it difficult to control desired film forming.

The above-mentioned ALD method is promising as a film forming technology that covers a structure having such a fine via hole or a very large aspect ratio.

However, the ALD method includes as one cycle the steps of (1) adsorbing a source material onto a surface of a substrate to be processed, (2) purging an excessive source material, (3) decomposing the source material adsorbed onto the surface of the substrate to be processed by a reduction gas or oxidation gas, and (4) purging by-products and remaining reaction gas, and the above steps need to be repeatedly performed, which results in a low film forming throughput.

Moreover, in an ALD method using an organic metal material, metal atoms are transferred onto a surface of the substrate to be processed while being coordinated with organic groups in source gas molecules in the step (1), and the metal atoms are deposited by removing the organic groups in the step (3). Accordingly, the metal atoms are not deposited on the portions of the surface of the substrate to be processed, which have been occupied by the organic groups, so that forming a metal film of one atom layer requires the cycle to be repeated in plural times.

### SUMMARY OF THE INVENTION

In accordance with an aspect of the present invention, there is provided a method of forming a metal film including: a first step of supplying a carbonyl material of a metallic element onto a surface of a substrate to be processed in a form of gas phase molecules along with a gas phase component suppressing a decomposition of the gas phase molecules, wherein a partial pressure of the gas phase component is set to a first partial pressure at which the decomposition of the gas phase molecules is suppressed; and a second step f changing the partial pressure of the gas phase component in the surface of the substrate to a second partial pressure which causes the decomposition of the carbonyl material to thereby deposit the metallic element on the surface of the substrate.

In accordance with another aspect of the present invention, there is provided a method of forming a multi-layer wiring structure including the steps of forming a recess in an insulation film; covering the insulation film including the recess with a barrier metal film in a shape conforming to the recess; forming a Ru film on the barrier metal film in a shape conforming to the recess; forming a Cu seed layer on the Ru film in a shape conforming to the recess; filling the recess with a Cu layer by electroplating the Ru film using the Cu seed layer as an electrode; and removing the Cu layer on a surface of the insulation film by chemical mechanical polishing.

Further, in the method of forming a multi-layer wiring structure, the step of forming the Ru film includes a first step of supplying a Ru₃(CO)₁₂ material onto the surface of the insulation film including the recess in a form of gas phase molecules along with CO gas, wherein a partial pressure of the CO gas is set to a first partial pressure at which a decomposition of the Ru₃ (CO)₁₂ material is suppressed; and a second step of changing the partial pressure of the CO gas to a second partial pressure which causes the decomposition of the Ru₃(CO)₁₂ material to thereby deposit Ru on the surface of the insulation film.

In accordance with still another aspect of the present invention, there is provided a method of manufacturing a semiconductor device having a multi-layer wiring structure, including the steps of forming a recess in an inter-layer insulation film constituting the multi-layer wiring structure; covering the inter-layer insulation film including the recess with a barrier metal film in a shape conforming to the recess; forming a Ru film on the barrier metal film in a shape conforming to the recess; forming a Cu seed layer on the Ru film in a shape conforming to the recess; filling the recess with a Cu layer by electroplating the Cu layer using the Cu seed layer as an electrode; and removing the Cu layer on a surface of the inter-layer insulation film by chemical mechanical polishing.

Further, in the method of manufacturing a semiconductor device having a multi-layer wiring structure, wherein the step of forming the Ru film includes a first step of supplying a Ru₃(CO)₁₂ material on the surface of the insulation film including the recess in a form of gas phase molecules along with CO gas, wherein a partial pressure of the CO gas is set to a first partial pressure at which a decomposition of the Ru₃(CO)₁₂ material is suppressed; and a second step of changing the partial pressure of the CO gas to a second partial pressure which causes the decomposition of the Ru₃(CO)₁₂ material to thereby deposit Ru on the surface of the insulation film.

In accordance with yet still another aspect of the present invention, there is provided a substrate processing apparatus including a processing chamber including a substrate supporting table that supports a substrate to be processed; a gas exhaust system for exhausting the processing chamber; a first gas supply system for supplying a gas of a metal carbonyl material to the processing chamber; a second gas supply system for supplying a gas suppressing a decomposition of the metal carbonyl material to the processing chamber; a third gas supply system for supplying an inert gas to the processing chamber; and a controller for controlling the first, second and third gas supply systems.

Further, in the substrate processing apparatus, the controller controls a flow rate of the inert gas in the third gas supply system, and changes a partial pressure of the gas suppressing the decomposition of the metal carbonyl material on the surface of the substrate in the processing chamber between a first partial pressure at which the decomposition of the metal carbonyl material is suppressed in the surface of the substrate and a second partial pressure which causes the decomposition of the metal carbonyl material in the surface of the substrate.

### EFFECTS OF THE INVENTION

In accordance with the present invention, a metallic element can be stably transferred and adsorbed onto a surface of a substrate to be processed in the form of a carbonyl material by adding a gas that suppresses a decomposition of the metal carbonyl material. Further, the metal carbonyl material adsorbed onto the surface of the substrate to be processed may be decomposed on the surface of the substrate by changing a partial pressure of the gas that suppresses the decomposition of the metal carbonyl material, whereby a desired metal layer can be formed on the surface of the substrate. Moreover, a film forming efficiency can be significantly enhanced and a film having a low impurity can be formed by repeating the above two steps in comparison with a conventional ALD process generally including four steps having a long term purge step.

The present invention is especially useful for forming an ultra fine multi-layer wiring structure which has a pattern width of 22 nm or less.

### BRIEF DESCRIPTION OF THE DRAWINGS

FIG. 1 illustrates a construction of a film forming apparatus in accordance with the present invention.

FIG. 2 is a view for explaining a principle of the present invention.

FIGS. 3A to 3D are views illustrating a film forming method in accordance with a first embodiment of the present invention.

FIG. 4 is a flowchart illustrating the film forming method in accordance with the first embodiment of the present invention.

FIGS. 5A to 5I are views illustrating a method of forming a multi-layer wiring structure in accordance with a second embodiment of the present invention.

### DETAILED DESCRIPTION OF THE EMBODIMENT

### First Embodiment

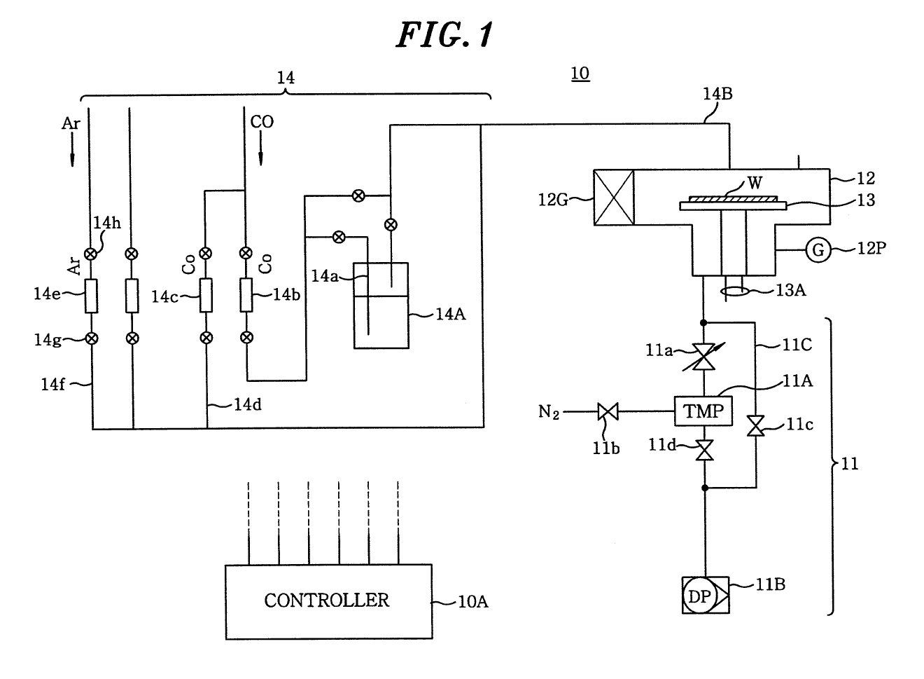

FIG. 1 illustrates a construction of a film forming apparatus 10 in accordance with a first embodiment of the present invention.

Referring to FIG. 1, the film forming apparatus 10 has a processing chamber 12 that is exhausted by a gas exhaust system 11 and provided with a substrate supporting table 13 that supports a substrate W to be processed, and a gate valve 12G is formed in the processing chamber 12 for loading and unloading the substrate W.

The substrate supporting table 13 has a heater (not shown) therein, and the heater is driven via a driving line 13A to maintain the substrate W at a desired processing temperature.

The gas exhaust system 11 has a configuration in which a turbo molecular pump 11A is connected in series with a dry pump 11B, and nitrogen gas is supplied to the turbo molecular pump 11A via a valve 11b. A variable conductance valve 11a is provided between the processing chamber 12 and the turbo molecular pump 11A, and a total pressure within the processing chamber 12 is maintained constantly. Further, the film forming apparatus 10 as shown in FIG. 1 has a gas exhaust path 11C that bypasses the turbo molecular pump 11A to roughly exhaust the processing chamber 12 by the dry pump 11B. In addition, a valve 11c is provided in the gas exhaust path 11C, and a separate valve 11d is provided at a downstream side of the turbo molecular pump 11A.

A film forming source gas is supplied from a source supply system 14, which includes a bubbler 14A, to the processing chamber 12 via a gas inlet line 14B in a gas phase.

In the example as shown, a carbonyl compound of Ru, Ru₃(CO)₁₂, is maintained in the bubbler 14A. The Ru₃(CO)₁₂ is vaporized and supplied to the processing chamber 12 via the gas inlet line 14B together with a CO carrier gas supplied from a line 14d, which includes a MFC (Mass Flow Controller) 14c, wherein the Ru₃(CO)₁₂ is vaporized by supplying CO gas as a bubbling gas from the bubbling gas line 14a including a MFC 14b.

Further, in the configuration as shown in FIG. 1, the source supply system 14 is provided with a line 14f, including valves 14g and 14h and a MFC 14e, for supplying an inert gas such as Ar or the like, and the inert gas is added to a Ru₃(CO)₁₂ gas that is supplied to the processing chamber 12 via the line 14B.

The film forming apparatus 10 further includes a controller 10A for controlling the processing chamber 12, the gas exhaust system 11, and the source supply system 14.

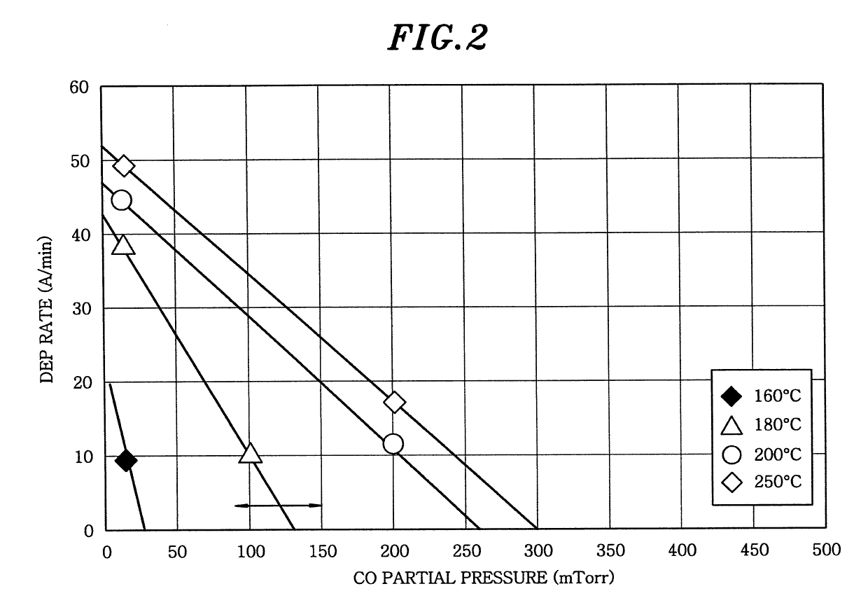

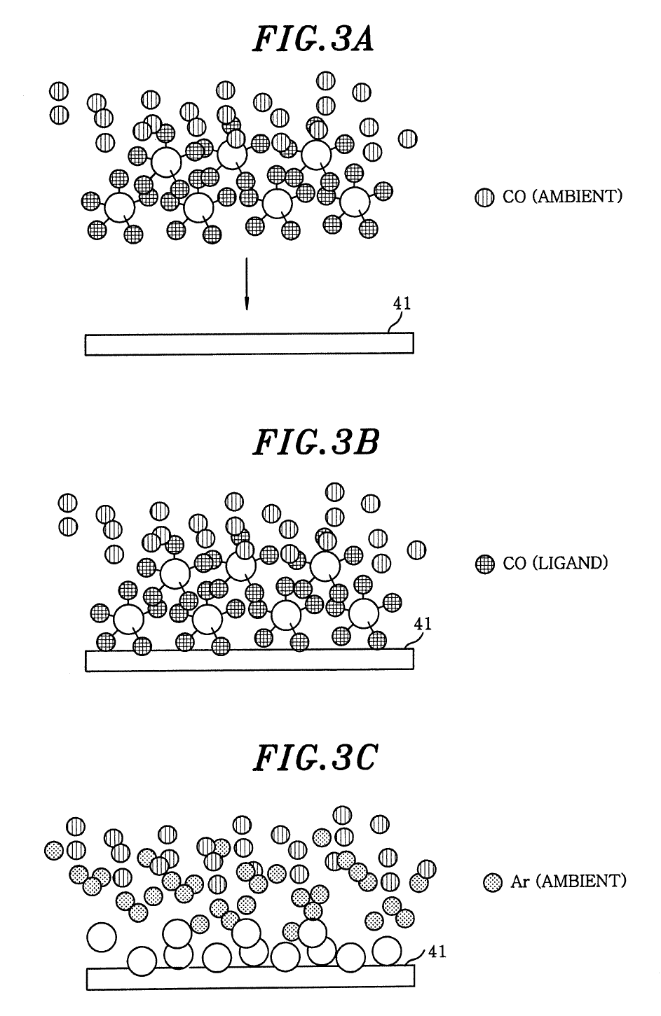

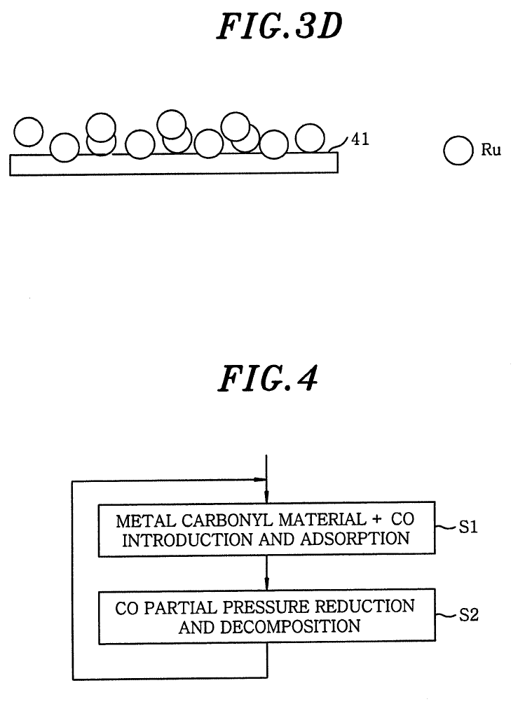

Hereinafter, film forming processes in accordance with a first embodiment of the present invention, which are performed using the film forming apparatus 10 as shown in FIG. 1, will be described with reference to FIG. 2, and FIGS. 3A to 3D.

The Ru₃(CO)₁₂ compound maintained in the bubbler 14A is easily decomposed by a reaction, Ru₃(CO)₁₂→3Ru+12CO, so that metallic Ru is precipitated out. In this reaction, if the partial pressure of CO, which is a reaction product, is low, the reaction proceeds toward the right side. Therefore, in the related art of the present invention, when a Ru film is formed on the substrate to be processed by a CVD method, a decomposition reaction is suppressed in a gas supply line by adding CO gas to an Ru₃(CO)₁₂ transfer atmosphere to control a CO partial pressure.

FIG. 2 illustrates results regarding a relationship between a deposition speed of a Ru film obtained by decomposing the Ru₃(CO)₁₂ material and a CO partial pressure in the atmosphere, which are inspected when a substrate temperature is 160° C., 180° C., 200° C., and 250° C., respectively, and this has been researched by the present inventors as a basis of the present invention.

Referring to FIG. 2, it can be seen that if a partial pressure of CO is low, Ru starts to be deposited even at any substrate temperature, and as the partial pressure of CO decreases, a deposition rate of Ru film increases.

For example, it can be seen that if the substrate temperature is 180° C., no Ru film is deposited (deposition rate is zero) under a CO partial pressure of 130 mTorr or more in the atmosphere, while a Ru film starts to be deposited at a rate if the CO partial pressure is below 130 mTorr.

The present inventors have conceived from the relationship shown in FIG. 2 that if a CO partial pressure within the processing chamber is changed by any means, e.g., in the substrate processing apparatus as shown in FIG. 1, formation of a Ru film, so-called ALD film forming, may be freely performed on the substrate W to be processed.

FIGS. 3A to 3D are views for explaining processes of a method of forming a Ru film in accordance with a first embodiment of the present invention on the basis of the above conception.

Referring to FIG. 3A, a Ru₃(CO)₁₂ material is supplied onto a substrate 41 to be processed, which corresponds to the substrate W as shown in FIG. 1, along with a high concentration CO atmosphere that suppresses its decomposition. Then, the Ru₃(CO)₁₂ material is adsorbed on a surface of the substrate 41 in the process as shown in FIG. 3B.

In the process as shown in FIG. 3C, if the concentration of CO is reduced by supplying an inert gas such as Ar gas to the atmosphere, the Ru₃(CO)₁₂ compound is immediately decomposed and consequently a Ru atomic layer is remained on the substrate 41 as shown in FIG. 3D. At that time, even though CO originating from a CO ligand is also generated, such an event that a CO bond is cut off and C is mixed with the Ru atomic layer does not take place. That is, it is possible to obtain a high-purity Ru layer in the process as shown in FIG. 3D.

Further, a proportion of CO originating from the ligand is ultimately low in the processes as shown in FIGS. 3C and 3D, so that, although it is released in the atmosphere, such a problem that a partial pressure of CO is increased to interrupt decomposition of the source compound does not occur. That is, it is not necessary to perform a purge process for a long time until reaction products are excluded from the system in the processes as shown in FIGS. 3A to 3D.

Thus, it is possible to form a Ru film with a specific thickness on the surface of the substrate by repeating the above processes. In the ALD process in accordance with this embodiment, it is not required to perform a long term purge process after an adsorption process of a source gas and another long term purge process after a reaction process, which are necessary in a conventional ALD process. Therefore, the Ru film is simply formed by repeating a source material introduction and adsorption process (step S1) and a CO partial pressure reduction and decomposition process (step S2) as shown in FIG. 4, so that a film forming throughput can be greatly increased. Here, FIG. 4 is a flowchart corresponding to processes as shown in FIGS. 3A to 3D, and the controller 10A controls the film forming apparatus 10 shown in FIG. 1 based on the flowchart shown in FIG. 4.

As an example, in the processes as shown in FIGS. 3A and 3B, Ru₃(CO)₁₂ gas is supplied at a flow rate of about 1 sccm together with CO gas whose flow rate is 70 to 100 sccm, but Ar gas is not supplied.

Further, in the processes as shown in FIGS. 3C and 3D, Ar gas is added at a flow rate of, e.g. 15 sccm while keeping the flow rates of the CO gas and the Ru₃(CO)₁₂ gas unchanged. At that time, an internal pressure of the processing chamber 12 may be measured, e.g., by a pressure gauge 12P provided in the processing chamber 12 and the controller 10A may control the conductance valve 11a based on the measurement results such that a total pressure in the processing chamber 12 is kept unchanged.

In the processes as shown in FIGS. 3A to 3D, further, it may be possible to transit a state of the film forming apparatus 10 from that shown in FIG. 3B to that shown in FIG. 3C by changing a total pressure of the processing chamber 12.

Further, although the above descriptions have been made as to a case where Ru₃(CO)₁₂ is used as a source material, the present invention is not limited to such a specific material. The present invention is also effective in a case where a metal film is formed using as a source material a metal carbonyl compound, such as, e.g., W(CO)₆, Ni(CO)₄, Mo(CO)₆, Co₂(CO)₈, Rh₄(CO)₁₂, Re₂(CO)₁₀, Cr(CO)₆, or the like.

In the processes as shown in FIGS. 3A to 3D, further, the substrate 41 serving as a base layer may be a silicon substrate, a silicon oxide film, or other dielectric films, or a metal film.

### Second Embodiment

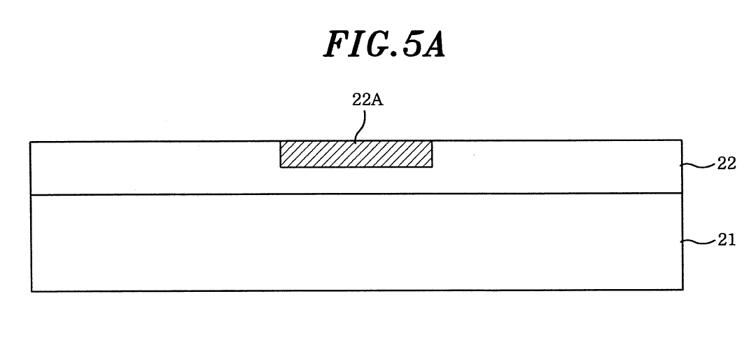

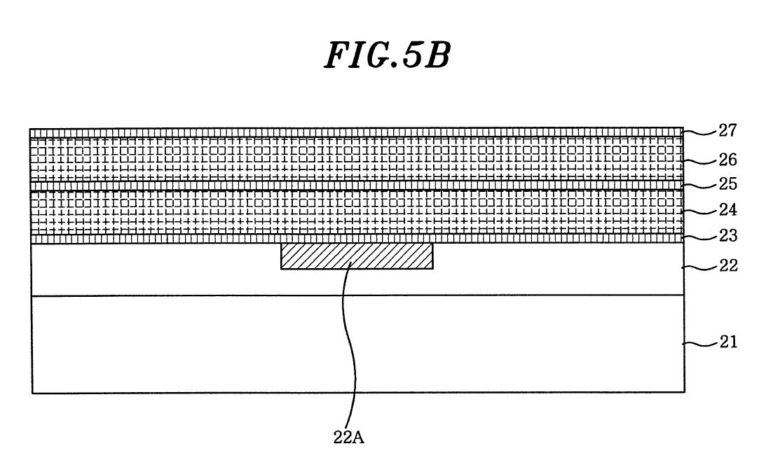

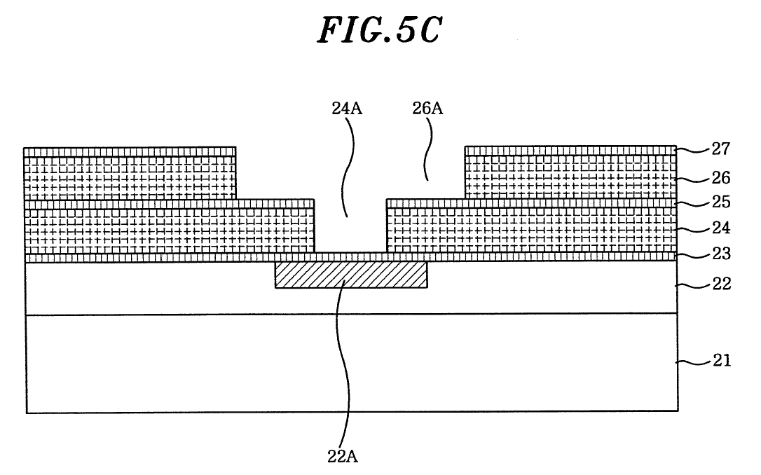

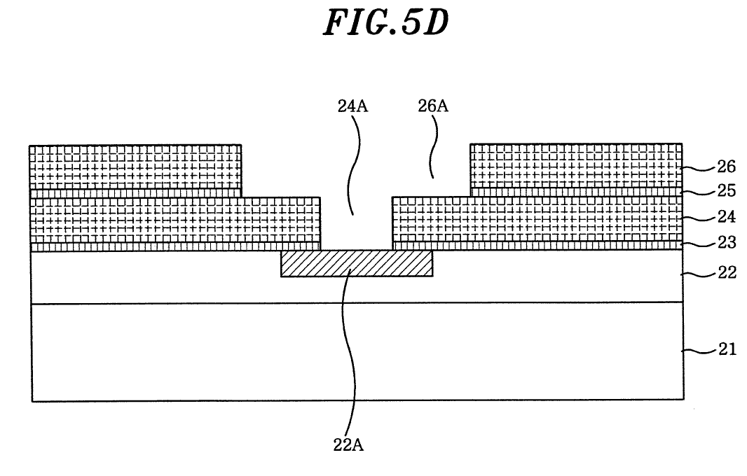

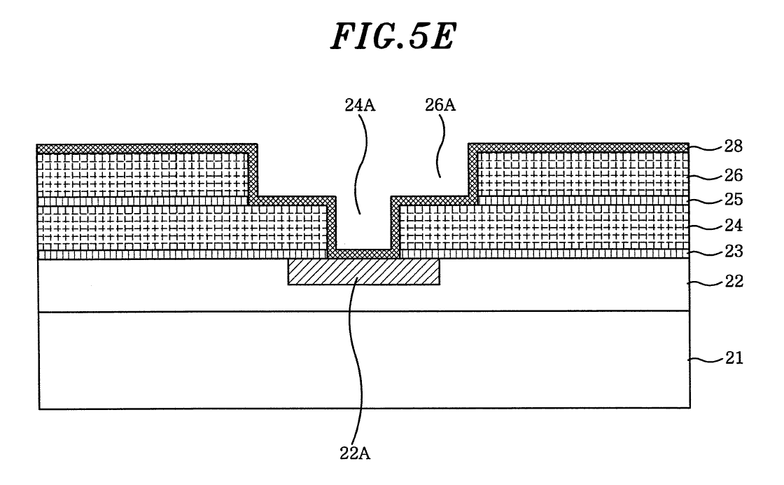

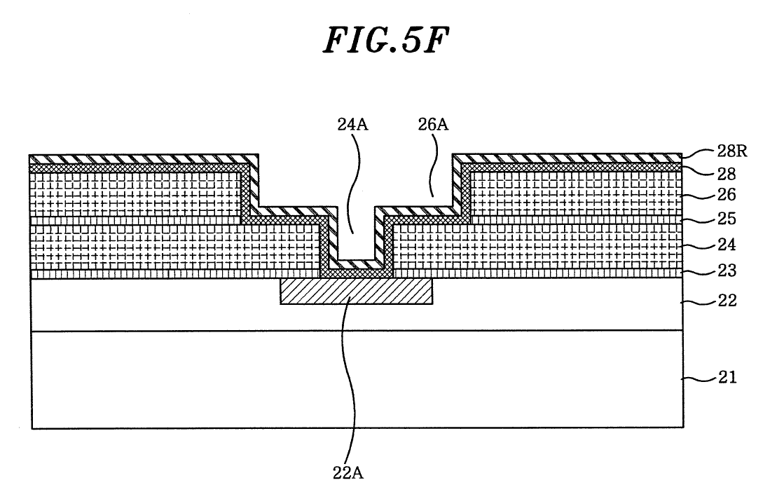

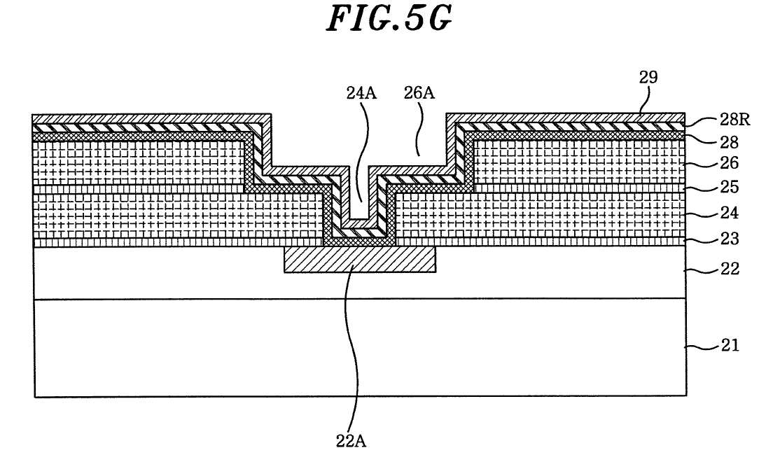

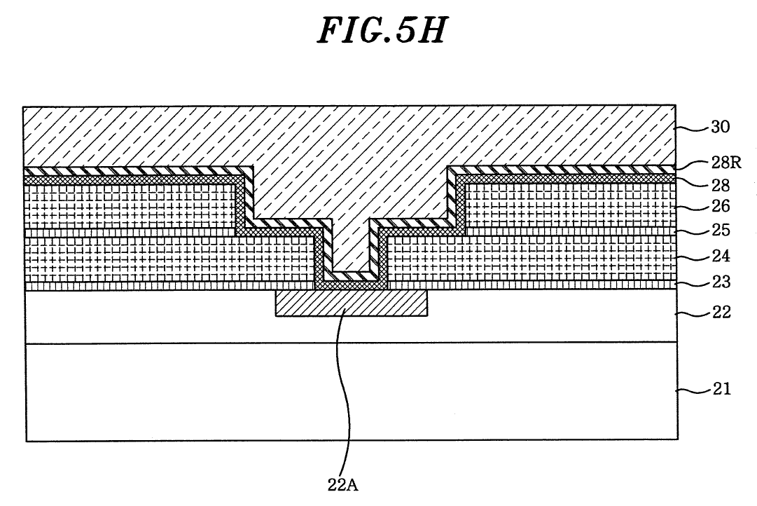

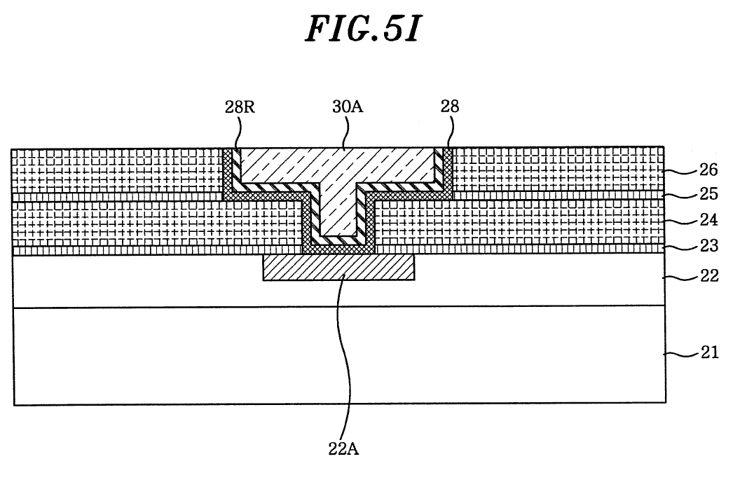

FIGS. 5A to 5I illustrate processes of manufacturing a multi-layer wiring structure in accordance with a second embodiment of the present invention.

Referring to FIG. 5A, a Cu pattern that has a thickness of 100 nm and a width of 0.1 μm is formed by a damascene method to be exposed on a surface of an SiO₂ film 22, which is formed to have a thickness of 200 nm on a silicon substrate 21. In the process as shown in FIG. 5B, an SiN barrier and etching stopper film 23, an SiCOH inter-layer insulation film 24, an SiN etching stopper film 25, an SiCOH inter-layer insulation film 26, and an SiN etching stopper film 27 are formed in this order on the structure shown in FIG. 5A by a plasma CVD method.

A film formed by a plasma CVD method, commercially available, may be used as the SiOCH film 24 and 26. In addition, when the SiOCH film 24 or 26 is formed, e.g., by a parallel plate type high-frequency plasma CVD apparatus, which is not shown, film forming may be conducted under conditions where a pressure is about 399 Pa (3 Torr), a substrate temperature is 25° C., flow rates of Ar gas and hydrogen gas are 50 SCCM and 500 SCCM, respectively, and high frequency power of 1000 W with 13.56 MHz is applied. Thus, the resulting SiOCH film 24 or 26 has a relative dielectric constant of about 3.0. In addition, the porous SiOCH film has a relative dielectric constant of about 2.2.

In the process of FIG. 5C, next, the SiN film 27 is patterned to have a desired wiring pattern by a photolithography process, which is not shown, and the inter-layer insulation film 26 is dry-etched by using the SiN film 27 as a hard mask until the SiN film 25 is exposed, to thereby form a groove 26A corresponding to the desired wiring pattern in the inter-layer insulation film 26.

In the process as shown in FIG. 5C, further, the SiN film 25 exposed in the groove 26A is patterned to have a desired via contact, the inter-layer insulation film 24 is dry-etched by using the SiN film 25 and the SiN film 27 as a hard mask until the SiN film 23 is exposed, to thereby form an opening 24A in the inter-layer insulation film 24 to have a diameter of, e.g. 16 nm or less, which corresponds to the via contact. In the process as shown in FIG. 5C, the order of the process of forming the groove 26A and the process of forming the opening 24A may be reversed.

Subsequently, in the process as shown in FIG. 5D, the SiN film 23 exposed at a bottom part of the opening 24A is removed by an etch back process to thereby expose the Cu wiring pattern at the bottom part of the opening 24A. Further, the SiN film 27 disposed on the inter-layer insulation film 26 is removed by performing an etch back process on the SiN film, and the SiN film 25 located at a bottom part of the groove 26A is removed.

Then, in the process as shown in FIG. 5E, a barrier metal film 28 obtained by laminating a TaN film and a Ta film is formed to have a film thickness of 2 nm to 3 nm on the structure shown in FIG. 5D by a so-called ALD method wherein the film forming is conducted by repeating a process of supplying a film forming gas and a process of supplying a reduction gas with a purge process therebetween.

Next, in the process as shown in FIG. 5F, the structure shown in FIG. 5E is introduced in the processing chamber 12 of the film forming apparatus 10 shown in FIG. 1, as described above, and a Ru film 28R is formed on the Ta film 28 to have a uniform film thickness of 2 nm to 3 nm by performing the processes as shown in FIGS. 3A to 3D, or FIG. 4.

In the process as shown in FIG. 5G, further, a Cu seed layer 29 is formed on the structure shown in FIG. 5F by an MOCVD method or ALD method, and in the process as shown in FIG. 5H, the structure shown in FIG. 5G is transferred to an electroplating apparatus, and a Cu layer 30 is formed on the Cu seed layer 29 by an electroplating method or electroless plating method.

Then, after a heat treatment, in the process as shown in FIG. 5I, the Cu layer 30 and underlying barrier metal film 28 located on the inter-layer insulation film 26 are polished and removed by a CMP (Chemical Mechanical Polishing) method to obtain a wiring structure having the groove 26A and the via hole 24A filled with a Cu pattern 30A.

Further, a multi-layer wiring structure having the structures shown in FIG. 5I one on top of another can be formed by repeating the processes as shown in FIGS. 5A to 5I.

In this embodiment, since the Ru film 28R is formed on the Ta film 28 to have a uniform film thickness by the ALD process as shown in FIGS. 3A to 3D or FIG. 4, the Cu seed layer 29 is uniformly formed thereon without causing agglomeration. Accordingly, film forming of the Cu layer 30 by a plating method using the seed layer 29 is also uniformly carried out without causing defects or voids, so that it is possible to obtain a Cu wiring pattern which is excellent in electro-migration resistance or stress migration resistance.

The present invention claims priority to Japanese Patent Application No. 2007-085021, filed on Mar. 28, 2007, the entire contents of which are hereby incorporated by reference.

Although the preferred embodiments of the present invention have been described above, various modifications or changes may be made within the scopes of the following claims without being limited to these specific embodiments.

What is claimed is:

1. A method of forming a metal film comprising:
a first step of supplying a carbonyl material including a metallic element onto a surface of a substrate to be processed along with a suppressor gas suppressing a decomposition of the carbonyl material, wherein a partial pressure of the suppressor gas is set to a first partial pressure at which the decomposition of the carbonyl material is suppressed; and
a second step of changing the partial pressure of the suppressor gas in the surface of the substrate to a second partial pressure which causes the decomposition of the carbonyl material to thereby deposit the metallic element on the surface of the substrate.

2. The method of claim 1, wherein the first step and the second step are alternately repeated.

3. The method of claim 2, wherein the carbonyl material are supplied onto the surface of the substrate, along with the suppressor gas and an inert gas, and the partial pressure of the suppressor gas is controlled by controlling the supply of the inert gas.

4. The method of claim 2, wherein the carbonyl material are supplied onto the surface of the substrate to be processed, along with the suppressor gas and an inert gas, and the partial pressure of the suppressor gas is controlled by selectively supplying the inert gas.

5. The method of claim 2, wherein the metallic element is any one of Ru, W, Ni, Mo, Co, Rh, Re, and Cr.

6. The method of claim 2, wherein the carbonyl material is any one of Ru₃(CO)₁₂, W(CO)₆, Ni(CO)₄, Mo(CO)₆, Co₂(CO)₈, Rh₄(CO)₁₂, Re₂(CO)₁₀, and Cr(CO)₆.

7. The method of claim 2, wherein the suppressor gas is CO gas.

8. A method of forming a multi-layer wiring structure comprising the steps of:
forming a recess in an insulation film;
covering the insulation film including the recess with a barrier metal film in a shape conforming to the recess;
forming a Ru film on the barrier metal film in a shape conforming to the recess;
forming a Cu seed layer on the Ru film in a shape conforming to the recess;
filling the recess with a Cu layer by electroplating the Cu layer using the Cu seed layer as an electrode; and
removing the Cu layer on a surface of the insulation film by chemical mechanical polishing, wherein the step of forming the Ru film includes:
a first step of supplying a Ru₃(CO)₁₂ material onto the surface of the insulation film including the recess along with CO gas, wherein a partial pressure of the CO gas is set to a first partial pressure at which a decomposition of the Ru₃(CO)₁₂ material is suppressed; and
a second step of changing the partial pressure of the CO gas to a second partial pressure which causes the decomposition of the Ru₃(CO)₁₂ material to thereby deposit Ru on the surface of the insulation film.

9. A method of manufacturing a semiconductor device having a multi-layer wiring structure, comprising the steps of:
forming a recess in an inter-layer insulation film constituting the multi-layer wiring structure;
covering the inter-layer insulation film including the recess with a barrier metal film in a shape conforming to the recess;
forming a Ru film on the barrier metal film in a shape conforming to the recess;
forming a Cu seed layer on the Ru film in a shape conforming to the recess;
filling the recess with a Cu layer by electroplating the Cu layer using the Cu seed layer as an electrode; and
removing the Cu layer on a surface of the inter-layer insulation film by chemical mechanical polishing, wherein the step of forming the Ru film includes:
a first step of supplying a Ru₃(CO)₁₂ material on the surface of the insulation film including the recess along with CO gas, wherein a partial pressure of the CO gas is set to a first partial pressure at which a decomposition of the Ru₃(CO)₁₂ material is suppressed; and
a second step of changing the partial pressure of the CO gas to a second partial pressure which causes the decomposition of the Ru₃(CO)₁₂ material to thereby deposit Ru on the surface of the insulation film.
